(19) United States
(12) Patent Application Publication
(10) Pub. No.: US 2009/0155684 A1
(43) Pub. Date: Jun. 18, 2009

(54) PROTECTION CIRCUIT ASSEMBLY AND BATTERY PACK HAVING THE SAME

(75) Inventors: Young-Cheol Jang, Suwon-si (KR); Jeong-Deok Byun, Suwon-si (KR)

Correspondence Address: STEIN MCEWEN, LLP, 1400 EYE STREET, NW, SUITE 300, WASHINGTON, DC, 20005, US

(73) Assignee: Samsung SDI Co., Ltd., Suwon-si (KR)

(21) Appl. No.: 12/270,122

(22) Filed: Nov. 13, 2008

(30) Foreign Application Priority Data
Dec. 13, 2007 (KR) 2007-129873

(51) Int. Cl. H01M 2/02; H05K 1/00

(52) U.S. Cl. 429/178; 174/250

(57) ABSTRACT

A protection circuit assembly and a battery pack including the same detachment of a lead plate from a protection circuit board. The battery pack includes a bare cell including a cap assembly having an electrode terminal and a cap plate; and a protection circuit assembly including; a protection circuit board having first and second connection terminals, a first lead plate to connect the first connection terminal to the cap plate, and a second lead plate to connect the second connection terminal to the electrode terminal, the second lead plate including a groove and/or a hole formed at one side connected in the second connection. A solder cream is applied to sides and upper edges of the lead plate to securely attach the second lead plate to the protection circuit board, thereby preventing the detachment of the second lead plate from the protection circuit board.

### CROSS-REFERENCE TO RELATED APPLICATIONS

This application claims the benefit of Korean Patent Application No. 2007-129873, filed Dec. 13, 2007, the disclosure of which is incorporated herein by reference.

### BACKGROUND OF THE INVENTION

1. Field of the Invention

Aspects of the present invention relate to a protection circuit assembly and a battery pack including the same, and more particularly, to a protection circuit assembly and a battery pack including the same capable of preventing detachment of a lead plate from a protection circuit board.

2. Description of the Related Art

Secondary batteries are more economical than disposable batteries since they are rechargeable. Moreover, since secondary batteries are getting smaller and have a higher capacity, they are widely used as power sources of handheld electronic/electrical appliances, such as mobile phones, notebook computers, camcorders, digital cameras, and the like.

Such secondary batteries include nickel-cadmium batteries, nickel-metal hydride batteries, nickel-zinc batteries, lithium secondary batteries, and lithium polymer secondary batteries. Among these secondary batteries, a lithium secondary battery is widely used due to its compact size, high capacity, high operating voltage, and higher energy density per unit weight than other batteries.

The lithium secondary battery is classified into a can type and a pouch type according to the shape of an outer casing in which an electrode assembly is disposed. The electrode assembly includes a positive electrode plate, a negative electrode plate, and a separator disposed therebetween. The can type may be further classified into a cylinder type and a prismatic type.

In the can-type lithium secondary battery, an outer casing is generally formed of a metal, such as aluminum, and may be formed in a cylinder shape, a prism shape, or a rod shape having rounded corners.

An opening is formed in an upper portion of a can, an electrode assembly is inserted into the can through the opening, and then an electrolyte is injected to fill the can. Subsequently, the can is sealed with a cap assembly having the size and shape corresponding to the opening of the can, and thus a sealed bare cell is completed.

In the pouch-type lithium secondary battery, an outer casing has an electrode assembly on a lower surface of the pouch casing having a space for accommodating the electrode assembly. Subsequently, an upper surface of the pouch casing covers the lower surface of the pouch casing, and sealing portions formed along edges of the upper and lower surfaces of the pouch casing are joined to each other to seal the casing, and thus a bare cell is formed.

The bare cell is electrically connected with a protection circuit board including a protection device to prevent damage to the battery due to abnormal operations, such as overcharging, overdischarging, or overcurrent.

Here, the protection circuit board has a lead plate to make an electrical connection with the bare cell, wherein the lead plate may be attached to the protection circuit board using a solder cream. However, the lead plate may be detached from the protection circuit board due to a continuous external impact.

### SUMMARY OF THE INVENTION

Aspects of the present invention provide a protection circuit assembly, and a battery pack including the same, which prevents the detachment of a lead plate from a protection circuit board.

According to aspects of the present invention, a protection circuit assembly includes: a protection circuit board including first and second connection terminals; a first lead plate connected to the first connection terminal; and a second lead plate connected to the second connection terminal and having a groove and/or a hole formed at one side connected in the second connection terminal.

According to aspects of the present invention, a battery pack includes: a bare cell including a cap assembly having an electrode terminal and a cap plate; and a protection circuit assembly including a protection circuit board having first and second connection terminals, a first lead plate to connect the first connection terminal to the cap plate, and a second lead plate to connect the second connection terminal to the electrode terminal, the second lead plate including a groove and/or a hole formed at one side connected in the second connection terminal.

According to aspects of the present invention, the second lead plate may include a welding part, a support formed along both edges of the welding part, and a connection part extending from an end of the support, the connection part being connected in the second connection terminal.

According to aspects of the present invention, the groove may be formed in an edge of the connection part.

According to aspects of the present invention, the hole may be formed in the center of the connection part.

According to aspects of the present invention, the hole may be symmetrically formed about the center of the connection part.

According to aspects of the present invention, the groove may have a curved shape, a polygonal shape, or an irregular shape.

According to aspects of the present invention, the hole may have a circular shape, a polygonal shape, or an irregular shape.

According to aspects of the present invention, the second connection terminal may be connected to the second lead plate by a solder cream.

According to aspects of the present invention, the solder cream may be applied to sides and upper edges of the second lead plate.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1A is an exploded perspective view of a bare cell according to an exemplary embodiment of the present invention;

FIG. 1B is an assembled cross-sectional view of the bare cell of FIG. 1A;

FIG. 2 is an exploded perspective view of a battery pack according to an exemplary embodiment of the present invention;

FIG. 3A is an exploded perspective view of a protection circuit board and a lead plate according to an exemplary embodiment of the present invention;

FIG. 3B is an assembled bottom view of the protection circuit board and the lead plate of FIG. 3A;

FIGS. 4A to 4C illustrate various shapes of a groove formed in a lead plate according to an exemplary embodiment of the present invention; and

FIGS. 5A to 5C illustrate various shapes of a hole formed in a lead plate according to an exemplary embodiment of the present invention.

### DETAILED DESCRIPTION OF THE EMBODIMENTS

Reference will now be made in detail to the present embodiments of the present invention, examples of which are illustrated in the accompanying drawings, wherein like reference numerals refer to the like elements throughout. The embodiments are described below in order to explain the present invention by referring to the figures. Moreover, in the drawings, the lengths and thicknesses of a layer and a region may be exaggerated for clarity.

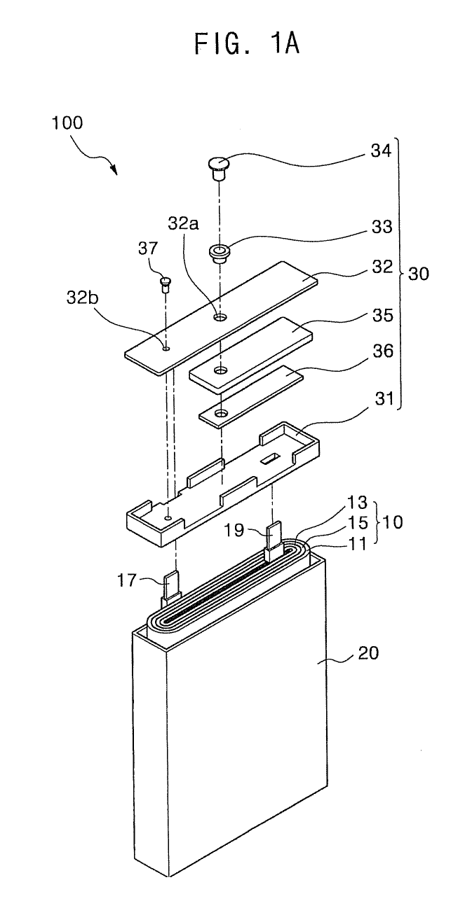

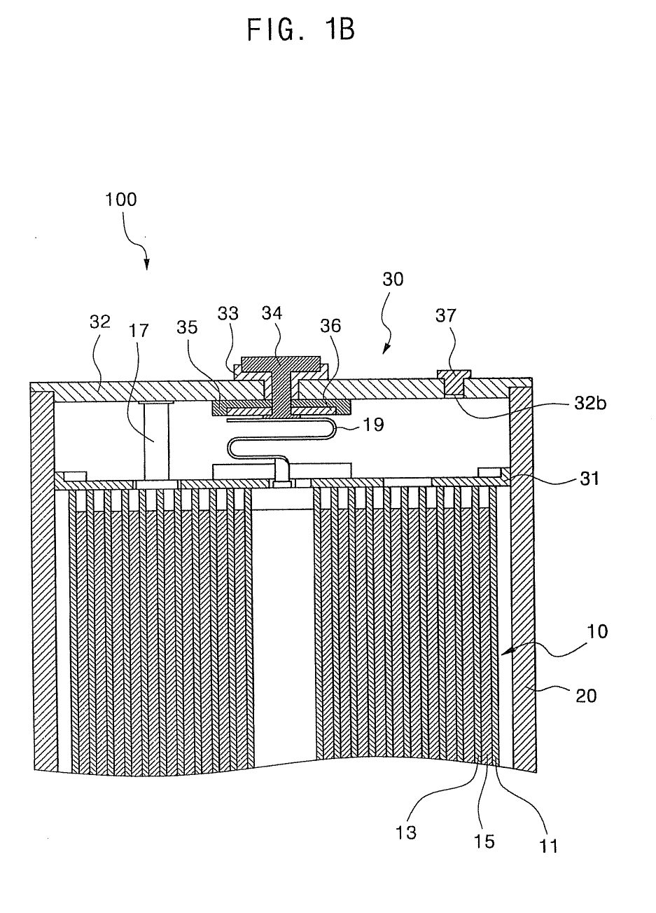

FIGS. 1A and 1B are exploded perspective and assembled cross-sectional views of a bare cell according to an exemplary embodiment of the present invention, respectively. Referring to FIGS. 1A and 1B, a bare cell 100 includes an electrode assembly 10, a can 20 for accommodating the electrode assembly 10, and a cap assembly 30 disposed on an opening of the can 20.

The electrode assembly 10 includes a positive electrode plate 11 formed by applying a positive electrode active material to a positive electrode collector, a negative electrode plate 13 formed by applying a negative electrode active material to a negative electrode collector, and a separator 15 disposed between the positive electrode plate 11 and the negative electrode plate 13 to prevent a short circuit between the positive and negative electrode plates 11 and 13 and to facilitate the migration of lithium ions therebetween. A positive electrode non-coating portion, i.e., a portion in which the positive electrode active material is not applied, is formed on the positive electrode plate 11, and a negative electrode non-coating portion, i.e., a portion in which the negative active material is not applied, is formed on the negative electrode plate 13.

A positive electrode tab 17 electrically connected to a cap plate 32 is joined to the positive electrode non-coating portion, and a negative electrode tab 19 electrically connected to an electrode terminal 34 is joined to the negative electrode non-coating portion. Here, the positive tab 17 and the negative tab 19 may be joined to the positive and negative electrode non-coating portions by ultra-sonic welding, but aspects of the present invention are not limited thereto. The positive electrode collector may be formed of stainless steel, nickel, aluminum, titanium, or alloys thereof, or carbon-, nickel-, titanium-, or silver-treated aluminum or stainless steel, and preferably aluminum or an aluminum alloy. The negative electrode collector may be formed of stainless steel, nickel, copper, titanium or an alloy thereof, or carbon-, nickel-, titanium-, or silver-treated cooper or stainless steel, and preferably copper or a copper alloy.

The separator 15 may be generally formed of a thermoplastic resin, such as polyethylene (PE) or polypropylene (PP), and has a porous surface. The porous separator 15 is melted at a temperature around a melting point of the thermoplastic resin due to an abnormal increase in internal temperature of the battery so that the porosity is blocked and the separator 15 becomes an insulating film. Thus, the migration of lithium ions between the positive and negative electrode plates 11 and 13 is interrupted to block the flow of current, thereby stopping an increase in internal temperature of the battery.

The can 20 may be formed of a metallic material having an opening at an upper portion thereof in which the electrode assembly 10 and the electrolyte are accommodated. The can 20 may also accommodate an insulating case 31 disposed the electrode assembly 10. The metallic material of which the can 20 may be formed may include aluminum, an aluminum alloy or stainless steel, which is light and flexible, and when the can 20 is formed of such a metallic material, it may have a polarity, and thus may be used as an electrode terminal. The shape of the can 20 may be prismatic or oval, and the open upper portion of the can 20 is welded or thermally fused with the cap plate 32 to be sealed.

The cap assembly 30 includes an insulating case 31, the cap plate 32, a gasket 33, the electrode terminal 34, the insulating plate 35, a terminal plate 36, and an electrolyte inlet plug 37.

The insulating case 31 is disposed on the electrode assembly 10, which is inserted into the can 20, and prevents movement of the electrode assembly 10. The insulating case 31 has an edge to which the terminal plate 36 and the insulating plate 35 covering the terminal plate 36 may be attached.

The cap plate 32 is connected to the opening of the can 20 to seal the opening of the can 20, has a size and a shape corresponding to the opening of the can 20, and has a through-hole 32a into which the gasket 33 and the electrode terminal 34 are inserted. The gasket 33 is connected to the through-hole 32a formed in the cap plate 32 and formed of an insulating material to insulate the electrode terminal 34 from the cap plate 32. Further, a hole is formed in the middle of the gasket 33 through which the electrode terminal 34 is connected to terminal plate 36. The electrode terminal 34 is connected to the cap plate 32 through the hole formed in the gasket 33, and the lower portion of the electrode terminal 34 is connected with the terminal plate 36 through the cap plate 32. Further, an electrolyte inlet 32b allows injection of an electrolyte into the can 10, is formed in the cap plate 32, and is sealed by the electrolyte inlet plug 37.

The insulating plate 35 is disposed under the cap plate 32 to insulate an outer surface of the terminal plate 36, and the insulating plate 35 has a hole through which the electrode terminal 34 and the terminal plate 36 are connected.

The terminal plate 36 is disposed under the insulating plate 35, i.e., between the insulating case 31 and the insulating plate 35, and formed of a conductive material. The terminal plate 36 connects the electrode terminal 34 with the negative tab 19, thereby making an electrical path between the negative electrode plate 13 of the electrode assembly 10 and the electrode terminal 34.

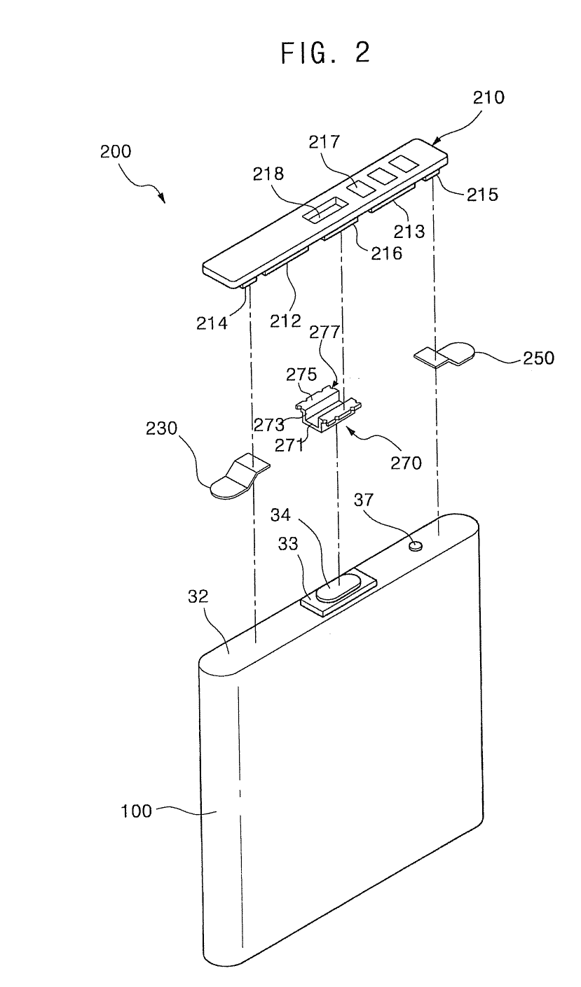

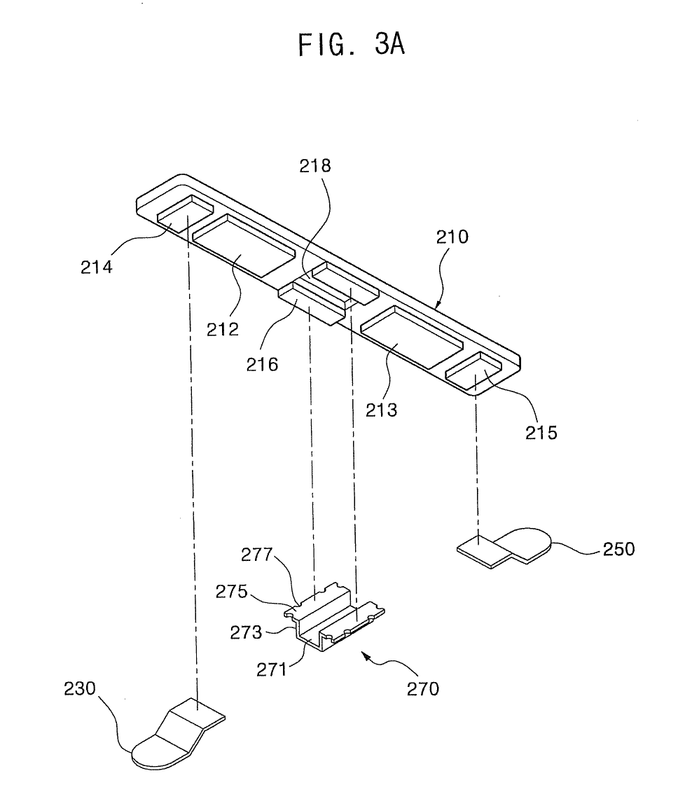

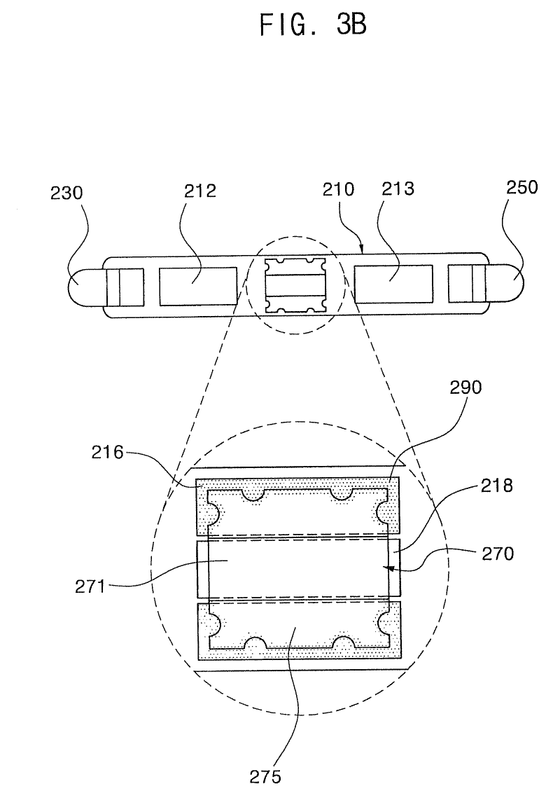

FIG. 2 is an exploded perspective view of a battery pack according to an exemplary embodiment of the present invention. FIG. 3A is an exploded perspective view of a protection circuit board and a lead plate according to an exemplary embodiment of the present invention, and FIG. 3B is an assembled bottom view of the protection circuit board and the lead plate of FIG. 3A.

Referring to FIGS. 2, 3A, and 3B, a battery pack includes a bare cell 100, and a protection circuit assembly 200 disposed at one side of the bare cell 100.

The protection circuit assembly 200 includes several lead plates 230, 250, and 270 to form electrical connections with the bare cell 100.

The bare cell 100 has the structure illustrated in FIGS. 1A and 1B in which an electrode terminal 34 insulated from a cap plate 32 by a gasket 33 and an electrolyte inlet plug 37 covering an electrolyte inlet (not shown) protrude from the cap plate 32 disposed at the upper portion of the bare cell 100.

The protection circuit assembly 200 includes the several lead plates 230, 250, and 270 to electrically connect a protection circuit board 210 with the bare cell 100. The protection circuit board 210 includes interconnection patterns formed therein, and a protection module 212, a positive temperature coefficient (PTC) thermistor 213, and connection terminals 214, 215, and 216 which are connected with the lead plates 230, 250, and 270 and are mounted on one side of the protection circuit board 210.

The protection circuit board 210 includes at least one external connection terminal 217 which is mounted on the other side, i.e., opposite the connection terminals 214, 215, and 216, of the protection circuit board 210. The at least one external connection terminal 217 is connectable with an external electronic and/or electrical appliances.

The protection circuit board 210 includes a hole 218 at one side of the protection circuit board 210, i.e., at a position corresponding to the electrode terminal 34 provided in the bare cell 100. The hole 218 the lead plate 270 to be welded to the electrode terminal 34 so as to electrically connect the bare cell 100 with the protection circuit board 210, and thus may be formed in a size to facilitate the welding process.

The lead plates connected to the connection terminals 214, 215, and 216 of the protection circuit board 210 include first lead plates 230 and 250 electrically connected with the cap plate 32 of the bare cell 100, and a second lead plate 270 in contact with the electrode terminal 34 of the bare cell 100. The first and second lead plates 230, 250, and 270 are generally formed of nickel having high conductivity, but aspects of the present invention are not limited thereto.

The first lead plates 230 and 250 may be provided to be connectable with the connection terminals 214 and 215 at edges of the protection circuit board 210 as illustrated in the present exemplary embodiment, all of which may be used as electrode lead plates to form an electrical path between the bare cell 100 and the at least one external connection terminal 217. Alternatively, one of the first lead plates 230 and 250 may be an electrode lead plate, and the other one of the first lead plates 230 and 250 may be an auxiliary lead plate to maintain a gap between the bare cell 100 and the protection circuit board 210.

The second lead plate 270 has one side electrically connected to the connection terminal 216 of the protection circuit board 210, and the other side electrically connected to the electrode terminal 34 of the bare cell 100 and the second lead plate 270 includes at least one groove 277 formed at the one side connected in the connection terminal 216.

The second lead plate 270 includes a planar welding part 271 which is welded to the electrode terminal 34 of the bare cell 100, a support 273 formed along both edges of the welding part 271, and a connection part 275 bent at an end of the support 273 and extending to be connectable to the connection terminal 216 of the protection circuit board 210. Although the planar welding part 271 is described and illustrated as planar, aspects of the present invention are not limited thereto such that the planar welding part 271 need not be planar. Here, at least one groove 277 may be formed in an edge of the connection part 275 of the second lead plate 270.

The connection part 275 of the second lead plate 270 may be connected to the connection terminal 216 of the protection circuit board 210 by soldering using a solder cream. Here, a contact area between the side surface of the connection part 275 and the solder cream 290 is increased by the groove 277 formed in the connection part 275 of the second lead plate 270.

Further, an adhesion strength between the connection part 275 and the connection terminal 216 increases when the solder cream 290 is applied to the upper edge of the connection part 275; thus, detachment of the second lead plate 270 from the protection circuit board 210 may be prevented.

In the present exemplary embodiment, the second lead plate 270 includes the welding part 271, the support 273, and the connection part 275 having the groove 277 formed in the edge thereof. However, the second lead plate 270 may have various shapes, and the position of the groove 277 may be also variously changed.

For example, the second lead plate 270 may be planar, and have a groove at one side of the planar surface, i.e., at a site corresponding to the connection terminal 216 of the protection circuit board 210.

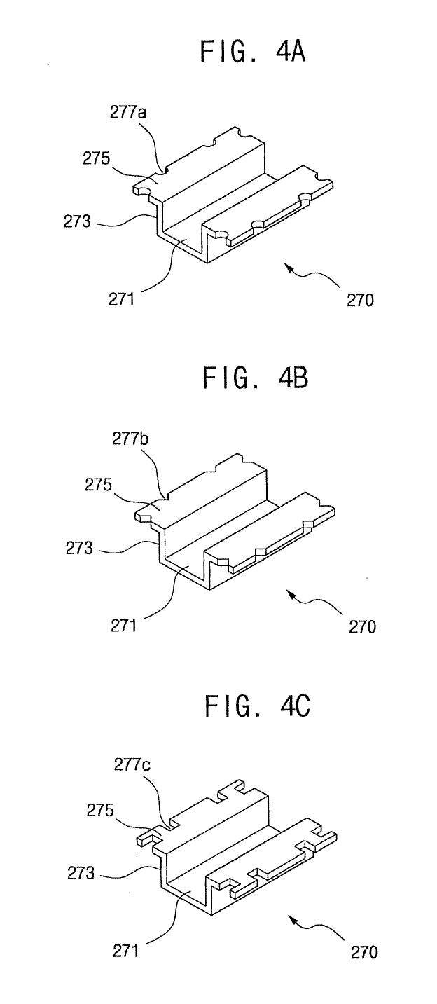

The groove 277 formed in the second lead plate 270, as illustrated in FIGS. 4A to 4C, may have a shape with a curvature 277a, or may be formed in a polygonal shape, such as a triangle 277b or a quadrangle 277c. Further, aspects of the present invention are not limited thereto such that groove 277 may be formed in different shapes when multiple grooves 277 are formed in the connection part 275. Further, the groove 277 is not limited to such shapes such that the groove 277 may be an irregular shape.

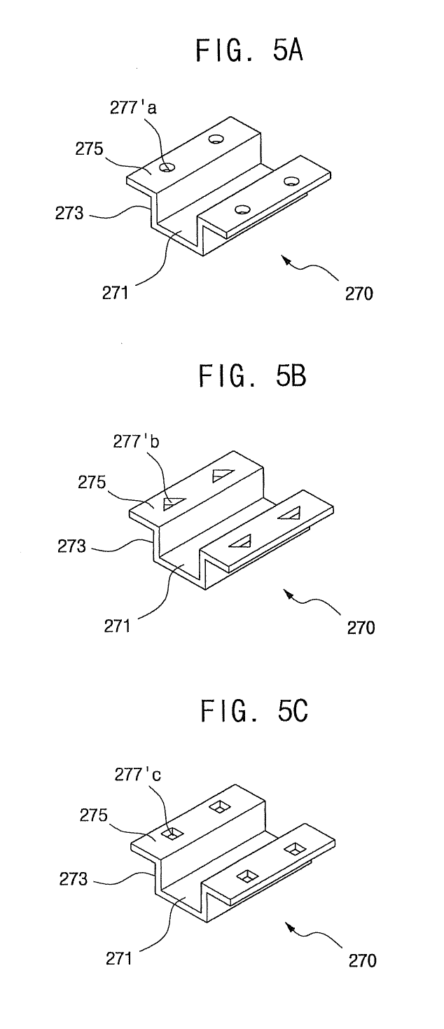

Alternatively, a hole 277′ may be formed instead of the groove 277. If one hole 277′ is formed, it may be formed in the center of the connection part 275, and if several holes 277′ are formed, the several holes 277′ may be symmetrically formed about the center of the connection part 275. But aspects of the present invention are not limited thereto such that the several holes 277′ or the one hole 277′ may be formed anywhere within the connection part 275. As illustrated in FIGS. 5A to 5C, the hole 277′ may have a circular shape 277′a, or a polygonal shape, such as a triangle 277′b or a quadrangle 277′c. Further, the several holes 277′ formed within the connection part 275 may include holes 277′ having different shapes. And the hole 277′ is not limited to circular or polygonal shapes such that hole 277′ may be an irregular shape.

According to aspects of the present invention, a solder cream is applied along upper edges and sides of a lead plate attached to a protection circuit board, and thus it is possible to prevent detachment of the lead plate from the protection circuit board.

Although a few embodiments of the present invention have been shown and described, it would be appreciated by those skilled in the art that changes may be made in this embodiment without departing from the principles and spirit of the invention, the scope of which is defined in the claims and their equivalents.

What is claimed is:

1. A protection circuit assembly, comprising:
a protection circuit board including first and second connection terminals;
a first lead plate connected to the first connection terminal; and
a second lead plate connected to the second connection terminal and having a groove and/or a hole formed at one side connected in the second connection terminal.

2. The protection circuit assembly of claim 1, wherein the second lead plate comprises:
a welding part,
a support formed along both edges of the welding part, and
a connection part extending from an end of the support, the connection part being connected in the second connection terminal.

3. The protection circuit assembly of claim 2, wherein the groove is formed in an edge of the connection part.

4. The protection circuit assembly of claim 2, wherein the hole is formed in the center of the connection part.

5. The protection circuit assembly of claim 2, wherein a plurality of the holes is symmetrically formed about the center of the connection part.

6. The protection circuit assembly of claim 1, wherein the groove has a curved, a polygonal, or an irregular shape.

7. The protection circuit assembly of claim 1, wherein the hole has a circular, elliptical, polygonal, or irregular shape.

8. The protection circuit assembly of claim 1, wherein the second connection terminal is connected to the second lead plate by a solder cream.

9. The protection circuit assembly of claim 8, wherein the solder cream is applied to sides and upper edges of the second lead plate.

10. The protection circuit assembly of claim 2, wherein the welding part is planar.

11. A battery pack, comprising:
a bare cell including a cap assembly having an electrode terminal and a cap plate; and
a protection circuit assembly comprising:
a protection circuit board having first and second connection terminals,
a first lead plate to connect the first connection terminal to the cap plate, and
a second lead plate to connect the second connection terminal to the electrode terminal, the second lead plate includes a groove and/or a hole formed at one side connected in the second connection.

12. The battery pack of claim 11, wherein the second lead plate comprises:
a welding part,
a support formed along both edges of the welding part, and
a connection part extending from an end of the support,
the connection part being connected in the second connection terminal.

13. The battery pack of claim 12, wherein the groove is formed at an edge of the connection part.

14. The battery pack of claim 12, wherein the hole is formed in the center of the connection part.

15. The battery pack of claim 12, wherein a plurality of the holes is formed symmetrically about the center of the connection part.

16. The battery pack of claim 11, wherein the groove has a curved, a polygonal, or an irregular shape.

17. The battery pack of claim 11, wherein the hole has a circular shape, a polygonal shape, or an irregular.

18. The battery pack of claim 11, wherein the second connection terminal is connected to the second lead plate by a solder cream.

19. The battery pack of claim 18, wherein the solder cream is applied to sides and upper edges of the second lead plate.

20. The battery pack of claim 12, wherein the welding part is planar.
